(19) United States
(12) Patent Application Publication
(10) Pub. No.: US 2015/0201167 A1
(43) Pub. Date: Jul. 16, 2015

(54) FABRICATION EQUIPMENT MONITORING DEVICE AND MONITORING METHOD

(71) Applicant: TOKYO ELECTRON LIMITED, Tokyo (JP)

(72) Inventors: Kaname Yamaji, Hokkaido (JP); Kazuya Uoyama, Yamanashi (JP); Yasuyuki Morita, Hokkaido (JP); Hiroaki Miyatake, Hokkaido (JP)

(73) Assignee: TOKYO ELECTRON LIMITED, Tokyo (JP)

(21) Appl. No.: 14/412,353

(22) PCT Filed: Jul. 2, 2013
(86) PCT No.: PCT/JP2013/004101

§ 371 Date: Dec. 31, 2014

(30) Foreign Application Priority Data
Jul. 3, 2012 (JP) 2012-149660

(51) Int. Cl. H04N 7/18; G06T 7/00; H04N 5/44

(52) U.S. Cl. CPC H04N 7/183; H04N 5/44; G06T 7/0004

(57) ABSTRACT

A fabrication equipment monitoring device which monitors, by a server and a portable terminal capable of communicating with the server, specifies the fabrication equipment toward which image capture element is faced, extracts the fabrication equipment information of the specified fabrication equipment from the storage unit based on the location information acquired by the location information acquisition unit, a direction information detected by the direction detection unit, an angle of view of the image capture element and the layout information when the image capture element is faced toward the fabrication equipment and displays at least a portion of the extracted fabrication equipment information on the display unit.

### TECHNICAL FIELD

The present invention relates to a fabrication equipment monitoring device and a fabrication equipment monitoring method.

### BACKGROUND ART

In the related art, a fabrication equipment constituted by a plurality of fabrication devices is utilized in fabricating, for example, a substrate for a semiconductor device or a flat panel display, or a solar cell panel. Further, the fabrication equipment is disposed inside a factory such as, for example, a clean room. A worker who works inside the factory such as the clean room obtains various infatuation generated from a fabrication equipment located at a remote site, from, for example, a buzzer sound or light-emitting of a revolving light.

An interface technique for a multi-dimensional digital image composite processing using a digital camera function in a portable phone is suggested in which a relative movement of an image of a subject captured by a digital camera is reflected on an arrow-pointer icon displayed to be superposed on data displayed on a monitor and a movement of other separate image data, using the digital camera function (see, e.g., Patent Document 1).

### PRIOR ART DOCUMENT

### Patent Document

Patent Document 1: Japanese Patent Laid-Open Publication No. 2006-285475

### SUMMARY OF INVENTION

### Problems to be Solved by the Invention

In the related art as described above, various information are generated from a device located at a remote site in a fabrication equipment inside a factory such as the clean room and obtained from a buzzer sound or light-emitting of a revolving light or the like. Accordingly, there is a problem in that the information to be obtained is limited and thus it is difficult to obtain detailed information.

The present invention has been made in an effort to cope with the problem described above and is intended to provide a fabrication equipment monitoring device and a fabrication equipment monitoring method that are capable of easily acquiring more information compared to the related art.

### Means to Solve the Problems

According to one aspect of the present invention, there is provided a fabrication equipment monitoring device which monitors, by a server and a portable terminal capable of communicating with the server, a fabrication equipment located inside a factory and including at least a plurality of fabrication devices. The portable terminal includes a location information acquisition unit configured to acquire location information about a current location of the portable terminal, an image capture element, a direction detection unit configured to detect a direction where the image capture element is directed, and a display unit. The server includes a storage unit configured to store layout information about a layout of the fabrication equipment inside the factory and fabrication equipment information about the fabrication equipment. When the image capture element is directed toward the fabrication equipment, the fabrication equipment toward which the image capture element is directed is specified based on the location information acquired by the location information acquisition unit, the direction information detected by the direction detection unit, an angle of view of the image capture element, and the layout information. The fabrication equipment information of the specified fabrication equipment is extracted from the storage unit, and at least a portion of the extracted fabrication equipment information is displayed on the display unit.

According to another aspect of the present invention, there is provided a fabrication equipment monitoring device which monitors, by a server and a portable terminal capable of communicating with the server, a fabrication equipment located inside a factory. The portable terminal includes a location information acquisition unit configured to acquire a location information about a current location of the portable terminal, a layout information acquisition unit configured to acquire layout information of the fabrication equipment, an image capture element, a direction detection configured to detect a direction where the image capture element is directed, and a display unit. The server includes a storage unit configured to store fabrication equipment information about the fabrication equipment inside the factory. When the image capture element is directed toward the fabrication equipment, the fabrication equipment toward which image capture element is directed is specified based on the location information acquired by the location information acquisition unit, the direction information detected by the direction detection unit, an angle of view of the image capture element and the layout information when the image capture element is faced toward the fabrication equipment. The fabrication equipment information of the specified fabrication equipment is extracted from the storage unit, and at least a portion of the extracted fabrication equipment information is displayed on the display unit.

According to another aspect of the present invention, there is provided a fabrication equipment monitoring method which monitors, by a server and a portable terminal capable of communicating with the server, a fabrication equipment located inside a factory and including at least a plurality fabrication devices. The portable terminal includes a location information acquisition unit configured to acquire location information about a current location of the portable terminal, an image capture element, a direction detection unit configured to detect a direction where the image capture element is directed, and a display unit. The server includes a storage unit is configured to store layout information about a layout of the fabrication equipment inside the factory and fabrication equipment information about the fabrication equipment. When the image capture is directed toward the fabrication equipment, the fabrication equipment toward which image capture element is directed is specified based on the location information acquired by the location information acquisition unit, the direction information detected by the direction detection unit, an angle of view of the image capture element, and the layout information. The fabrication equipment information of the specified fabrication equipment is from the storage unit, and at least a portion of the extracted fabrication equipment information is displayed on the display unit.

According to another aspect of the present invention, there is provided a fabrication equipment monitoring method which monitors, by a server and a portable terminal capable of communicating with the server, a fabrication equipment located inside a factory. The portable terminal includes a location information acquisition unit configured to acquire a location information about a current location of the portable terminal, an acquisition unit configured to acquire layout information of the fabrication equipment, an image capture element, a direction detection unit configured to detect a direction where the image capture element is directed, and a display unit. The server includes a storage unit configured to store a fabrication equipment information about the fabrication equipment inside the factory. When the image capture element is directed toward the fabrication equipment, the fabrication equipment toward which image capture element is directed is specified based on the location information acquired by the location information acquisition unit, the direction information detected by the direction detection unit, an angle of view of the image capture element, and the layout information. The fabrication equipment information of the specified fabrication equipment is extracted from the storage unit, and at least a portion of the extracted fabrication equipment information is displayed on the display unit.

### Effect of the Invention

According to the present invention, it is possible to provide a fabrication equipment monitoring device and a fabrication equipment monitoring method that are capable of easily acquiring more information compared to the related art.

### BRIEF DESCRIPTION OF DRAWINGS

FIG. 1 is a view illustrating a schematic configuration of a fabrication equipment monitoring device according to an embodiment of the present invention.

FIG. 2 is a view illustrating a schematic configuration of a portable terminal of the fabrication equipment monitoring device illustrated in FIG. 1.

FIG. 3 is a view illustrating a schematic configuration of a data structure of the fabrication equipment monitoring device illustrated in FIG. 1.

FIG. 4 is a view illustrating a schematic configuration of the data structure of the fabrication equipment monitoring device illustrated in FIG. 1.

FIG. 5 is a view for explaining a method of specifying an equipment ID of the fabrication equipment.

FIG. 6 is a flowchart illustrating operations of the fabrication equipment monitoring device illustrated in FIG. 1.

FIG. 7 is another flowchart illustrating operations of the fabrication equipment monitoring device illustrated in FIG. 1.

FIG. 8 is a view diagrammatically illustrating an example of a displayed image.

### DETAILED DESCRIPTION

Hereinafter, embodiments of the present invention will be described with reference to the accompanying drawings.

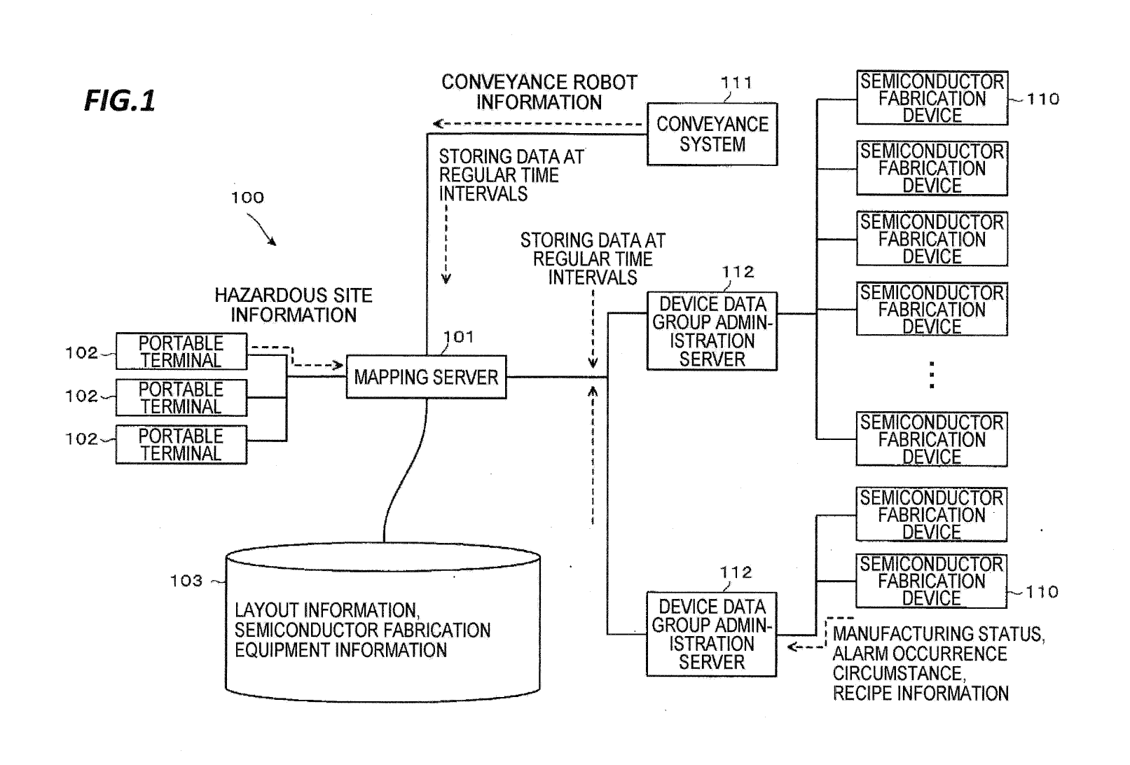

FIG. 1 is a view illustrating a schematic configuration of a fabrication equipment monitoring device according to an embodiment of the present invention. As illustrated in FIG. 1, a fabrication equipment monitoring device 100 includes a mapping server 101 and a plurality of portable terminals 102. The mapping server 101 and the portable terminal 102 are configured to be capable of communicating with each other.

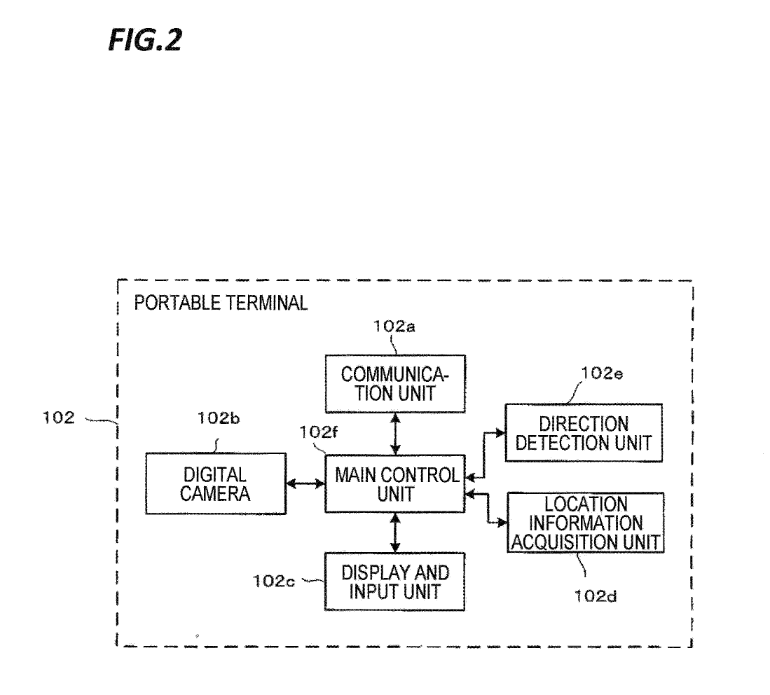

As illustrated in FIG. 2, the portable terminal 102 includes a communication unit 102a configured to communicate with the mapping server 101. Further, each of the portable terminals 102 includes an image capture element such as a digital camera 102b, a display and input unit 102c configured to display an image captured by the digital camera 102b and input the image by, for example, a touch panel, a location information acquisition unit 102d configured to acquire a location information about the current location of the portable terminal 102, a direction detection unit 102e configured to detect a direction image-captured by the digital camera 102b, and a main control unit 102f configured to control the entire portable terminal 102.

Further, the portable terminal 102 is adapted to allow the user to manually input and register hazardous site information within the clean room, for example, a site where danger of falling may be caused due to removal of a grating, in the mapping server 101. For example, a smartphone, a tablet PC, or a wearable computer may be used as the portable terminal 102. Further, these devices may include a transmissive display device.

Further, in FIG. 1, reference numeral 110 indicates a plurality of semiconductor fabrication devices disposed in the clean room and reference numeral 111 indicates a conveyance system configured to convey, for example, a semiconductor wafer to the semiconductor fabrication devices 110. For example, an MES (Manufacturing Execution System) or a wafer conveyance mechanism similar to the MES is utilized as the conveyance system 111. Also, conveyance robot information (e.g., information on a location of a conveyance robot) in the conveyance system 111 is stored in the mapping server 101 at regular time intervals.

Further, information about each semiconductor fabrication device 110, for example, the information such as a manufacturing status, an alarm occurrence circumstance, and recipe information are collected by a device data group administration server 112. Also, data collected by the device data group administration server 112 are stored in the mapping server 101 at regular time intervals.

The mapping server 101 includes a storage unit 103. The storage unit 103 stores, for example, an identifier (ID) for specifying the semiconductor fabrication equipment within the clean room, layout information (map information) about the layout of the semiconductor fabrication equipment within the clean room, and various information (semiconductor fabrication equipment information) indicating, for example, a status of the semiconductor fabrication equipment. The semiconductor fabrication equipment information includes, for example, operation situation summary information, operation rate transition information (one day, one week, one month, or one year), conveyance robot location information, an operation manual (e.g., PDF) of, for example, each of the semiconductor fabrication devices. Further, “the semiconductor fabrication equipment” includes the conveyance system 111 and various objects installed within the clean room in addition to the semiconductor fabrication devices 110 which perform various processings on, for example, a semiconductor wafer.

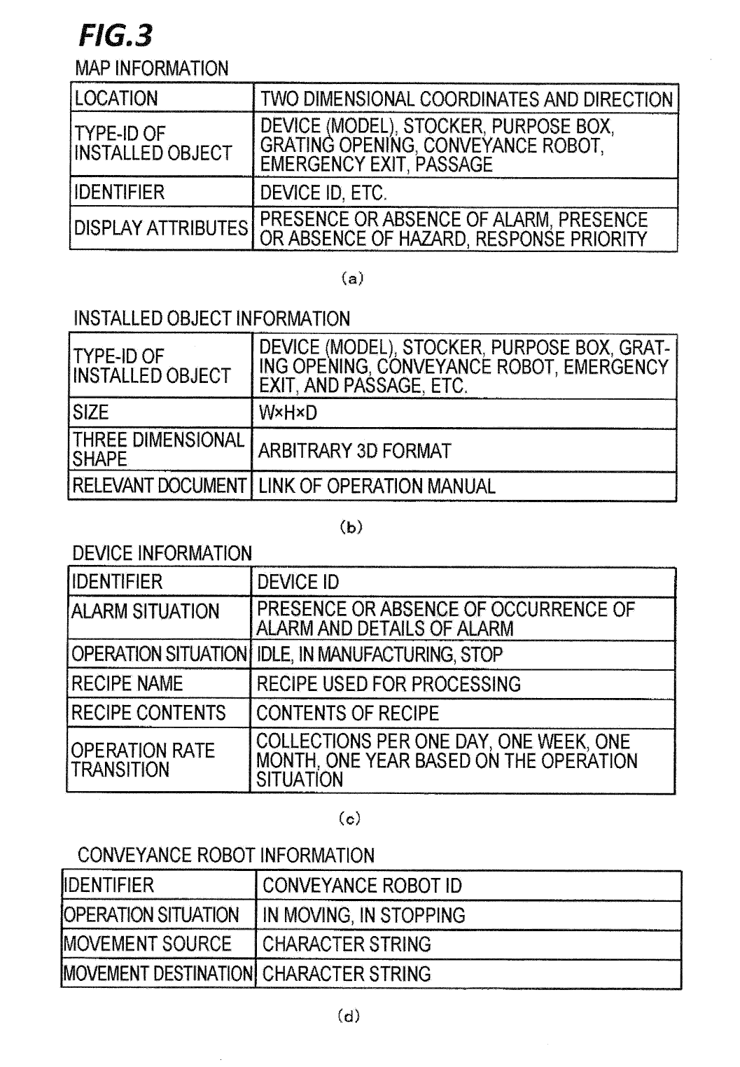

FIG. 3 is a view illustrates examples of data structures of various information stored in the storage means 103 of the mapping server 101. FIG. 3(a) illustrates an example of the map information constituting the layout information, FIG. 3(b) illustrates an example of the installed object information, FIG. 3(c) illustrates an example of the device information, and FIG. 3(d) illustrates an example of the conveyance robot information.

As illustrated in FIG. 3(a), the map information are, for example, a location (X-coordinate and Y-coordinate of a two-dimensional coordinate system and direction), a type-ID of an installed object (a device (model), a stocker, a purpose box, a grating opening, a conveyance robot, an emergency exit, or a passage), an identifier (e.g., a device ID), and a display attribute (presence or absence of an alarm, presence or absence of hazard, or response priority).

As illustrated in FIG. 3(b), the installed object information are, for example, the type-ID of the installed object (e.g., the device (model), the stocker, the purpose box, the opening in the grating, the conveyance robot, the emergency exit, or the passage), a size (W×H×D), a three dimensional shape (an arbitrary 3D format), and a relevant document (link of an operation manual).

As illustrated in FIG. 3(c), the device information are, for example, the identifier (device ID), the alarm situation (presence or absence of occurrence of an alarm and details of the alarm), the operation situation (idle, in manufacturing, or stop), a recipe name (a recipe used for a processing), recipe contents (contents of the recipe used for the processing), and an operation rate transition (collected per one day, one week, one month, or one year based on the operation situation).

As illustrated in FIG. 3(d), the conveyance robot information are, for example, the identifier (conveyance robot ID), the operation situation (in moving or in stopping), a movement source (character string), and a movement destination (character string).

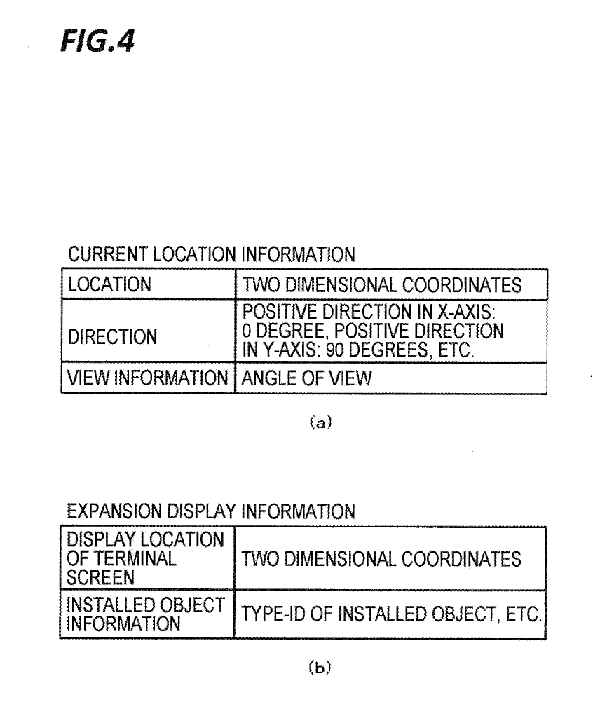

FIG. 4 is a view illustrates examples of data structures of the portable terminal 102. FIG. 4(a) illustrates an example of the current location information and FIG. 4(b) illustrates an example of expansion display information. As illustrated in FIG. 4(a), the current location information include, for example, a location (X-coordinate and Y-coordinate of a two-dimensional coordinate system), a direction (e.g., a positive direction in X-axis: 0 degree, a positive direction in Y-axis: 90 degrees, a negative direction in X-axis: 180 degrees, or a negative direction in Y-axis: 270 degrees), and view information (an angle of view (a unique value for each terminal)).

Further, as illustrated in FIG. 4(b), the expansion display information are, for example, a display location (e.g., (S, T) of a two dimensional coordinate system) of the terminal screen and installed object information (e.g., type-ID of installed object, device ID, and-conveyance robot ID).

Each portable terminal 102 is constituted by, for example, a smartphone, a tablet PC, or a wearable computer as described above, and includes the display and input unit 102c constituted by, for example, an image capture element such as the digital camera 102b and the liquid crystal display as illustrated in FIG. 2. Also, the portable terminal 102 is adapted to capture an image of the semiconductor fabrication equipment within the clean room by the digital camera 102b and display the captured image on the display screen of the display and input unit 102c.

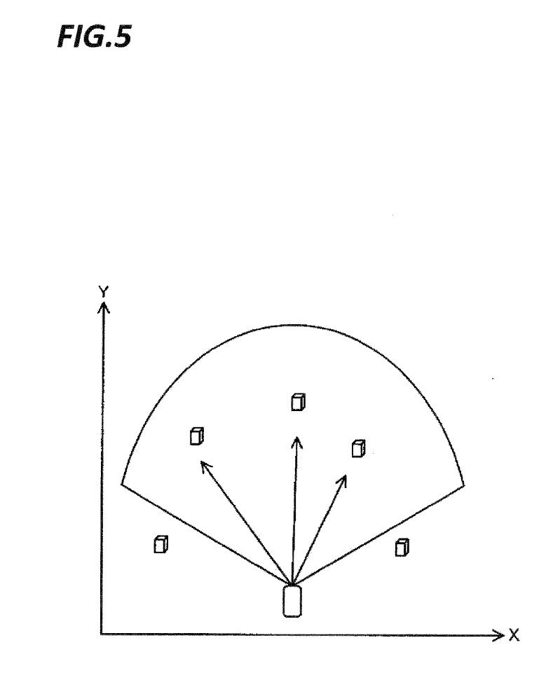

Further, the portable terminal 102 includes a location information acquisition unit 102d that acquires the location information about the current location of the portable terminal 102 and a direction detection unit 102e that detects an image-capturing direction by the digital camera 102b (a direction where the digital camera 102b is directed). Therefore, for example, as illustrated in FIG. 5, when an image of the semiconductor fabrication equipment within the clean room is captured by the digital camera 102b and displayed on the display screen of the display and input unit 102c, it is possible to obtain information concerning the location and direction where the obtained image has been captured. Further, the location information acquisition function and the direction detection function described above may be implemented by, for example, communicating with a portable base station or a wireless access point and using a sensor such as, for example, a 6-axis sensor (tri-axial geomagnetic sensor and tri-axial acceleration sensor).

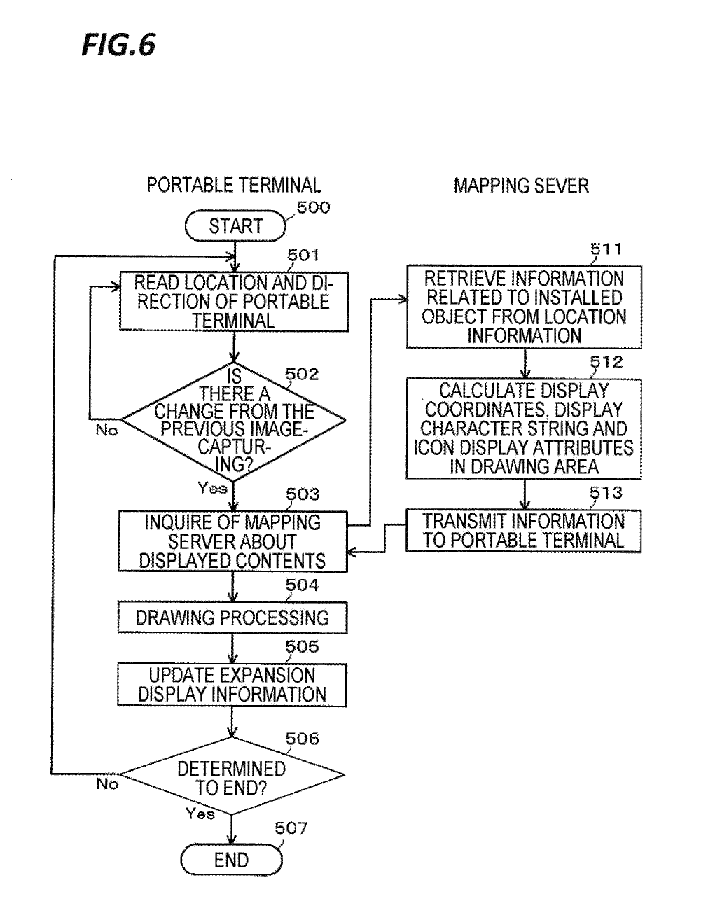

Next, descriptions will be made on monitoring of the semiconductor fabrication equipment by the mapping server 101 and a portable terminal 102 with reference to a flowchart of FIG. 6. The worker who performs the monitoring captures an image of the semiconductor fabrication equipment disposed within the clean room using the digital camera of the portable terminal 102 and displays the image on the display device to start a monitoring mode in this state (step 500). Further, the image-capturing of the semiconductor fabrication equipment may be performed through, for example, a window at the outside of the clean room.

First, the portable terminal 102 reads the location and direction of the portable terminal 102 (step 501). Next, the portable terminal 102 determines whether there is a change from the previous image-capturing (step 502). When it is determined that there is a change, the portable terminal 102 transmits the location information (a location in a XY coordinate system, a direction, and an angle of view) to the mapping server 101 and inquires of the mapping server 101 about the displayed contents (step 503). In the meantime, when there is no change, the portable terminal 102 repeats a process which is started from step 501.

In the mapping server 101, the identifier (e.g., device ID) of an installed object displayed on image is specified from the location information (a location in a XY coordinate system, a direction, and an angle of view) transmitted from the portable terminal 102 based on the map information described above, and the information related to the installed object is retrieved (step 511). Next, the display coordinates, the display character string and the icon display attributes in the drawing area (an ST coordinate system) for displaying the information about the retrieved installed object are calculated (step 512). Also, the calculated information and the information about the presence or absence of (presence or absence of other display information) of the installed object label are transmitted to the portable terminal (step 513).

After receiving the information from the mapping server 101, the portable terminal 102 performs the drawing processing based on the information such as, for example, the display coordinates, the display character string, or the icon display attributes, and displays the information about the installed object retrieved in the mapping server 101 on the location designated by the display coordinates on the display screen of the portable terminal 102 based on the display character string and the icon display attributes (step 504).

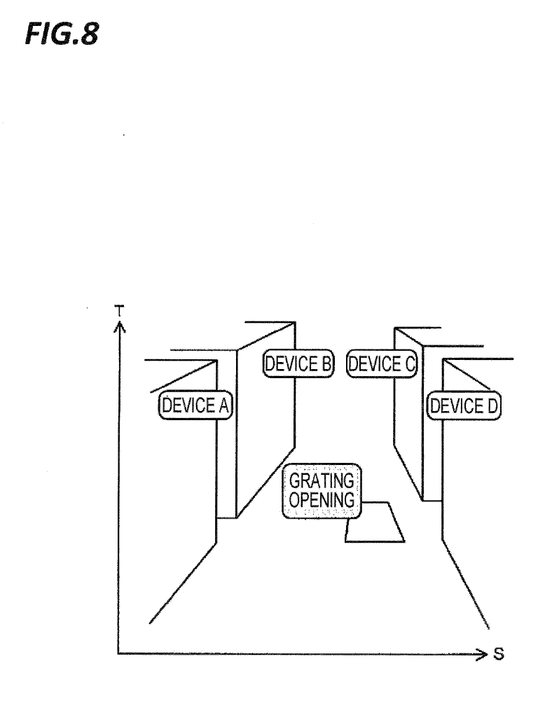

An example of the display screen for the case is illustrated in FIG. 8. In the example of the display screen illustrated in FIG. 8, for example, the device name (DEVICE A to DEVICE D) labels of the semiconductor fabrication devices are displayed together with the semiconductor fabrication devices displayed on the display screen, for example, by incrementing the device name labels by T sequentially from the nearest object so that the device name labels do not overlap with each other and a part where a portion of the grating is removed to form an opening is displayed as “GRATING OPENING”. Further, since the “GRATING OPENING” becomes the information which represents the hazardous state, it is indicated to be different from the indication of the device name. For example, it is indicated using a color different from the color indicating the device name (e.g., “GRATING OPENING” is indicated by a red color while the device names are indicated by a yellow color). Further, in the example of the display screen illustrated in FIG. 8, although a plurality of the semiconductor fabrication devices are illustrated on a single display screen, a worker capture an image of only one semiconductor fabrication device, for example, by standing in front of the one semiconductor fabrication device, and only the captured semiconductor fabrication device information may be displayed on the display screen.

Next, in the portable terminal 102, the expansion display information is updated (step 505), and then it is determined whether to end the process (step 506). When it is determined not to end the process, the process from step 501 is repeated. In the meantime, when it is determined to end the process, the process is ended (step 507).

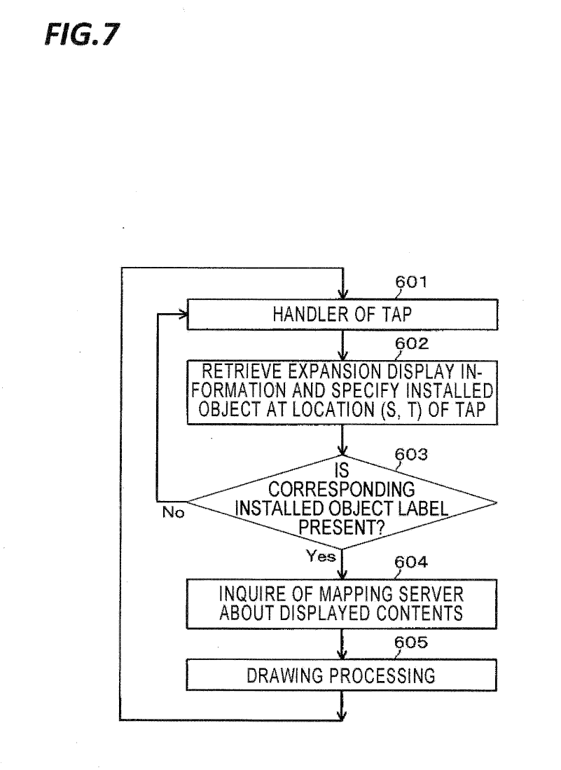

Further, after the process, as illustrated in FIG. 7, when the specific location on the display screen is tapped and the handler on the tap is activated in the portable terminal 102 (step 601), the expansion display information is retrieved at the location (S, T) of tap to specify an installed object (step 602).

Then, it is determined whether an installed object label corresponding to the installed object is present or absent (step 603), and when it is determined that the installed object label corresponding to the installed object is present, the portable terminal 102 inquires of the mapping server 101 about the displayed contents (step 604) and performs the drawing processing based on the information transmitted from the mapping server 101 to display the information (step 605). In this case, the displayed contents are, for example, the size the three dimensional shape and the relevant document (e.g., an operation manual) of the installed object. In the case of a semiconductor device, the displayed contents are an alarm situation, an operation situation, a recipe name, recipe contents, an operation rate transition, and in the case of a conveyance robot, the displayed contents are, for example, the operation situation, the movement source, and the movement destination. In the meantime, when there is no corresponding installed object label, the process is ended.

The portable terminal 102 may have a function that allows each user to select a display mode to customize display (notification) information (e.g., hazardous site information and device information). In this case, for example, the display mode and the display information may be customized as follows.

Safety inspection mode: notification of alarm in CR and notification of update of hazardous site information (grating opening information)

Line engineer mode: notification of alarm in CR, notification of update of hazardous site information (grating opening information), notification of process alarm, and notification of maintenance cycle announcement

FE mode: notification of alarm in CR, notification of update information of hazardous site information (grating opening information), and notification of information process termination announcement

Operator mode: notification of alarm in CR, and notification of update of hazardous site information (grating opening information)

When each user selects the display mode to customize the display information (e.g., hazardous site information and device information) as described above, necessary display information may be displayed according to the user.

Further, the portable terminal 102 may have functions of sending the image information captured by the digital camera 102b, and the location information and the direction information about the captured location to the mapping server 101, and updating various information stored in the storage means 103 in order to share the information.

For example, in a case where a new “grating opening” for which the information is absent in the mapping server 101 occurs, since this information is the information which indicates hazard (hazardous site information), it is preferable that the information is shared between persons who enter the clean room. In this case, the image of the “grating opening” is captured by the digital camera 102b of the portable terminal 102. The captured image information, the location information and the direction information are sent to the mapping server 101. In this case, the image information within the portable terminal 102 may be automatically cleared for security so as to prevent the image information from being taken out to the outside.

The mapping server 101 updates the map information and the information about the “grating opening” of the installed object information from the image information, the location information, and the direction information sent from the portable terminal 102. Also, the mapping server 101 transmits the updated information to each portable terminal 102 and the updated information is displayed on each portable terminal 102.

In this manner, in the case where the “grating opening” for which the information is absent in the mapping server 101 exists, the information about the “grating opening” may be shared between users who carry the portable terminals, respectively.

Further, in a case where no network is available within the clean room, the portable terminal 102 may be put closer to an NFC tag disposed near to an exit when leaving the clean room to activate an application software of the portable terminal 102 using communication with the NFC tag as a trigger so that the captured image information, the location information, and the direction information may be sent to the mapping server 101 and the image information within the portable terminal 102 may be cleared. Also, in this case, the mapping server 101 updates the map information and the information about the “grating opening” of the installed object information from the image information and the location information sent from the portable terminal 102. Then, the mapping server 101 transmits the updated information to each portable terminal 102 to be displayed on the portable terminal 102

Further, the portable terminal 102 may obtain the location information in the following manner. That is, a worker downloads the map information (connecting data of identifier (ID) of the semiconductor fabrication equipment and the location information) into the portable terminal 102 when entering the clean room.

Then, the worker enters the clean room and stands in front of the semiconductor fabrication equipment (a semiconductor fabrication device 110) to obtain the identifier (ID) information thereof. The identifier (ID) information may be obtained by, for example, any one of the following methods.

A method of obtaining the identifier (ID) information by lighting a signal tower of a semiconductor fabrication device 110 with a specific pattern or color, and recognizing the lighting by the digital camera 102b of the portable terminal 102.

A method of obtaining the identifier (ID) information by displaying a QR code on the screen of the semiconductor fabrication device 110, and recognizing the QR code by the digital camera 102b of the portable terminal 102.

A method of obtaining the identifier (ID) information by attaching an NFC tag stored with the identifier (ID) information of the semiconductor fabrication device 110 to the semiconductor fabrication device 110, and putting the portable terminal 102 closer to the NFC tag.

A method of obtaining the identifier (ID) by causing a specific buzzer to sound from the semiconductor fabrication device 110, and recognizing the sound by a microphone of the portable terminal 102 to calculate the identifier (ID) information from the type of the buzzer

A method of obtaining the identifier (ID) information by capturing an image of a top screen of the semiconductor fabrication device 110 by the digital camera 102b of the portable terminal 102, and comparing the device state (e.g., an alarm and an execution recipe name) with the information of the device data group administration server 112.

Also, with the portable terminal 102, the current location is grasped from the map information (the connecting data of the identifier (ID) and the location information) downloaded when entering the clean room and the identifier (ID) information of the semiconductor fabrication device 110. Further, upon having moved from the location, the current location is predicted based on the value of, for example, the above-mentioned 6-axis sensor (tri-axial geomagnetic sensor and tri-axial acceleration sensor).

Further, in a state where the NFC tag is attached to the specific point within the clean room in advance, the map information (connecting data of a specific point and the location information) is downloaded on the portable terminal 102 when entering the clean room. Upon having entered the clean room, the portable terminal 102 is put closer to the NFC tag at the specific point to grasp the current location. Also, in this case, upon having moved therefrom, the current location is predicted based on the value of, for example, the above-mentioned 6-axis sensor (tri-axial geomagnetic sensor and tri-axial acceleration sensor).

Further, there is generally a limitation in using a network or portable terminal in the clean room in terms of security. Therefore, the fabrication equipment monitoring device 100 may have a function that inquires of whether the portable terminal 102 is allowed to be carried in the clean room when the worker has the portable terminal and enters the clean room.

In this case, the portable terminal 102 is put closer to the NFC tag for authorization when entering the clean room. An authentication function within the portable terminal 102 is activated using communication with the NFC tag as a trigger so that when “permission OK information” is present within the portable terminal 102, the portable terminal 102 is allowed to use the application software and shifts to a use mode within the clean room. In this case, for example, Bluetooth is turned OFF, 3G is turned OFF, and GPS is turned OFF.

Further, when the “permission OK information” is absent within the portable terminal 102, for example, the MAC address of the portable terminal 102 is ascertained, for example, by inquiring of the device data group administration server 112 about the MAC address of the portable terminal 102. When the portable terminal 102 is not allowed to be carried into the clean room, the application software of the portable terminal 102 is made to be unavailable (invalidation of device function) and, for example, the camera function is invalidated, Bluetooth is turned OFF, 3G is turned OFF, GPS is turned OFF.

Further, the portable terminal 102 has a function that when a specific semiconductor fabrication device 110 is image-captured by the digital camera 102b, the display of the portable terminal 102 is able to show a status inside of the device as an image similarly to an opened window of the semiconductor fabrication device 110. This may be implemented by combining the image captured by the portable terminal 102 and the image captured by the camera disposed within the semiconductor fabrication device 110 and displaying the combined image on the display of the portable terminal 102.

This function is activated by tapping, for example, the image of the semiconductor fabrication device 110 displayed on the display of the portable terminal 102, and the image of the panned camera disposed within the semiconductor fabrication device 110 may be displayed by panning (circulating the direction) the portable terminal 102. In this way, it is possible to ascertain a shape inside the device without opening a maintenance door.

Further, the portable terminal 102 has a function of displaying a state at the rear side of the semiconductor fabrication device 110 in a state where the semiconductor fabrication device 110 is absent when the specific semiconductor fabrication device 110 is image-captured by the digital camera 102b. That is, when an image of a camera disposed behind the semiconductor fabrication device 110 is subjected to a projection mapping to be superposed on the surface of the semiconductor fabrication device 110 in the AR space, an image of a state where the semiconductor fabrication device 110 is absent is displayed. This function is activated by tapping, for example, the image of the semiconductor fabrication device 110 displayed on the display of the portable terminal 102. In this manner, it is possible to perform a safety confirmation of the rear side of the semiconductor fabrication device 110 which becomes a blind spot.

As described above, according to the present embodiment, when a semiconductor fabrication equipment such as a semiconductor fabrication device 110 is image-captured by a digital camera 102b of a portable terminal 102, the information, such as, for example, the device name, the device state, the device operation manual of the semiconductor fabrication device 110 may be displayed to overlap with the captured image. Further, the hazardous site information of, for example, a grating opening where, for example, a worker is in danger of falling. Therefore, the larger amount of information about the semiconductor fabrication equipment may be easily acquired compared to the related art.

Further, the present invention is not limited to the embodiment described above and various modifications may also be made thereto.

### INDUSTRIAL APPLICABILITY

The fabrication equipment monitoring device and the fabrication equipment monitoring method of the present invention may be used in the manufacturing field of a substrate for a semiconductor device or a flat panel display, or a solar cell panel. Therefore, the present invention has an industrial applicability.

### EXPLANATION OF SYMBOLS

100: fabrication equipment monitoring device, 101: mapping server, 102: portable terminal, 103: storage means, 110: semiconductor fabrication device, 111: conveyance system

What is claimed is:

1. A fabrication equipment monitoring device which monitors, by a server and a portable terminal capable of communicating with the server, a fabrication equipment located inside a factory and including at least a plurality of fabrication devices,
wherein the portable terminal includes a location information acquisition unit configured to acquire location information about a current location of the portable terminal, an image capture element, a direction detection unit configured to detect a direction where the image capture element is directed, and a display unit, and
the server includes a storage unit configured to store layout information about a layout of the fabrication equipment inside the factory and fabrication equipment information about the fabrication equipment, and
wherein, when the image capture element is directed toward the fabrication equipment, the fabrication equipment toward which the image capture element is directed is specified based on the location information acquired by the location information acquisition unit, the direction information detected by the direction detection unit, an angle of view of the image capture element, and the layout information,
the fabrication equipment information of the specified fabrication equipment is extracted from the storage unit, and
at least a portion of the extracted fabrication equipment information is displayed on the display unit.

2. The fabrication equipment monitoring device of claim 1, wherein the portable terminal is configured to send a captured image, the location information acquired by the location information acquisition unit, and the direction information detected by the direction detection unit to the server to update the fabrication equipment information.

3. The fabrication equipment monitoring device of claim 1, wherein the portable terminal is configured to set the fabrication equipment information to be displayed on the display unit in advance by selecting a display mode.

4. The fabrication equipment monitoring device of claim 1, wherein information about a grating opening is included in the fabrication equipment information.

5. The fabrication equipment monitoring device of claim 1, wherein information about an operation rate transition of the fabrication device is included in the fabrication equipment information.

6. The fabrication equipment monitoring device of claim 1, wherein information about an operation manual of the fabrication device is included in the fabrication equipment information.

7. The fabrication equipment monitoring device of claim 1, wherein information about a location of a conveyance robot in a conveyance system is included in the fabrication equipment information.

8. The fabrication equipment monitoring device of claim 1, wherein the portable terminal is detects a location of the portable terminal from the identification information of the fabrication equipment and the layout information.

9. The fabrication equipment monitoring device of claim 1, wherein, when the fabrication equipment is image-captured by the image capture element, the portable terminal is configured to acquire an image of the inside of the image-captured fabrication equipment and an image behind the image-captured fabrication equipment from the server and display the images.

10. A fabrication equipment monitoring device which monitors, by a server and a portable terminal capable of communicating with the server, a fabrication equipment located inside a factory,
wherein the portable terminal includes a location information acquisition unit configured to acquire location information about a current location of the portable terminal, a layout information acquisition unit configured to acquire layout information of the fabrication equipment, an image capture element, a direction detection unit configured to detect a direction where the image capture element is directed, and a display unit, and
the server includes a storage unit configured to store fabrication equipment information about the fabrication equipment inside the factory, and
wherein, when the image capture element is directed toward the fabrication equipment, the fabrication equipment toward which the image capture element is directed is specified based on the location information acquired by the location information acquisition unit, the direction information detected by the direction detection unit, an angle of view of the image capture element, and the layout information,
the fabrication equipment information of the specified fabrication equipment is extracted from the storage unit, and
at least a portion of the extracted fabrication equipment information is displayed on the display unit.

11. A fabrication equipment monitoring method which monitors, by a server and a portable terminal capable of communicating with the server, a fabrication equipment located inside a factory and including at least a plurality of fabrication devices,
wherein the portable terminal includes a location information acquisition unit configured to acquire location information about a current location of the portable terminal, an image capture element, a direction detection unit configured to detect a direction where the image capture element is directed, and a display unit, and
the server includes a storage unit configured to store layout information about a layout of the fabrication equipment inside the factory and fabrication equipment information about the fabrication equipment, the method comprising:
when the image capture element is directed toward the fabrication equipment, specifying the fabrication equipment toward which the image capture element is directed based on the location information acquired by the location information acquisition unit, the direction information detected by the direction detection unit, an angle of view of the image capture element, and the layout information,
extracting the fabrication equipment information of the specified fabrication equipment from the storage unit, and
displaying at least a portion of the extracted fabrication equipment information on the display unit.

12. A fabrication equipment monitoring method which monitors, by a server and a portable terminal capable of communicating with the server, a fabrication equipment located inside a factory,
wherein the portable terminal includes a location information acquisition unit configured to acquire location information about a current location of the portable terminal, a layout information acquisition unit configured to acquire layout information of the fabrication equipment, an image capture element, a direction detection unit configured to detect a direction where the image capture element is directed, and a display unit, and
the server includes a storage unit store fabrication equipment information about the fabrication equipment inside the factory, the method comprising:
when the image capture element is directed toward the fabrication equipment, specifying the fabrication equipment toward which the image capture element is directed based on the location information acquired by the location information acquisition unit, the direction information detected by the direction detection unit, an angle of view of the image capture element, and the layout information;
extracting the fabrication equipment information of the specified fabrication equipment is extracted from the storage unit; and
displaying at least a portion of the extracted fabrication equipment information is displayed on the display unit.
